(19) United States
(12) Patent Application Publication
(10) Pub. No.: US 2025/0385119 A1
(43) Pub. Date: Dec. 18, 2025

(54) ELECTROSTATIC CHUCK

(71) Applicant: TOTO LTD., Fukuoka (JP)

(72) Inventors: Yuki SASAKI, Fukuoka (JP); Jun SHIRAISHI, Fukuoka (JP); Ikuo ITAKURA, Fukuoka (JP)

(73) Assignee: TOTO LTD., Fukuoka (JP)

(21) Appl. No.: 19/236,482

(22) Filed: Jun. 12, 2025

(30) Foreign Application Priority Data
Jun. 18, 2024 (JP) 2024-098077

(51) Int. Cl. H01L 21/683; H01J 37/32

(52) U.S. Cl. CPC H01L 21/6833; H01J 37/32568

(57) ABSTRACT

An electrostatic chuck 10 includes a dielectric substrate 100, an internal electrode 140 provided inside the dielectric substrate 100, a base plate 200 in which a through hole 230 is formed, a power supply member 400 that is a member for supplying power to the internal electrode 140 and is inserted through the through hole 230, and an insulating member 500 arranged between an inner surface of the through hole 230 and the power supply member 400. The insulating member 500 includes a tubular first insulating member 510, and a tubular second insulating member 520 covering a part of the first insulating member 510 on an outer peripheral side. The electrostatic chuck 10 further includes an annular member 530 for preventing an electric discharge along a path from the power supply member 400 to the inner surface of the through hole 230 passing between the first insulating member 510 and the second insulating member 520.

### CROSS-REFERENCE TO RELATED APPLICATION

This application is based upon and claims the benefit of priority from Japanese Patent Application No. 2024-098077 filed on Jun. 18, 2024, the entire contents of which are incorporated herein by reference.

### FIELD

The present invention relates to an electrostatic chuck.

### BACKGROUND

For example, in a semiconductor manufacturing apparatus such as an etching apparatus, an electrostatic chuck is provided as an apparatus configured to adsorb and hold a wafer such as a silicon wafer to be processed. The electrostatic chuck includes a dielectric substrate inside which an adsorption electrode is provided and a base plate which supports the dielectric substrate, and has a configuration in which these are joined to each other. When a voltage is applied to the adsorption electrode, an electrostatic force is generated, and the wafer placed on the dielectric substrate is adsorbed and held.

An RF electrode may be provided inside the dielectric substrate. The RF electrode is used as one of a pair of counter electrodes for generating plasma in the semiconductor manufacturing apparatus. A voltage is applied also to the RF electrode from an outside.

Electrodes provided inside the dielectric substrate such as the above-described adsorption electrode and RF electrode are also collectively referred to as “internal electrodes” hereinafter. As disclosed in Japanese Patent Laid-Open No. 2015-222748, a power supply member for supplying power to the internal electrode is provided in the electrostatic chuck. The power supply member is inserted through a through hole passing through a base plate, and electrically connected to the internal electrode of the dielectric substrate.

### SUMMARY

To prevent an electric discharge to/from the power supply member, an upper end to a lower end of a whole inner surface of the through hole of the base plate is preferably covered by an insulating member. The present inventors have examined a configuration using, as the above-described insulating member, a tubular first insulating member and a tubular second insulating member that covers a part of the first insulating member on an outer peripheral side. With a configuration in which two tubular members are overlapped with each other, even when variation is caused in dimensions of each member, the whole inner surface of the through hole of the base plate can be easily and securely covered.

However, with the above-described configuration, an electric discharge may be caused between the power supply member and the base plate on a path passing through a gap between the first insulating member and the second insulating member.

The present invention has been made in view of such a problem and aims at providing an electrostatic chuck in which an electric discharge between a power supply member and a base plate can be prevented.

To solve the problem described above, the electrostatic chuck according to the present invention includes a dielectric substrate including a placement surface on which an object to be adsorbed is placed, an internal electrode provided inside the dielectric substrate, a base plate that is a metal member supporting the dielectric substrate, and in which a through hole is formed, a power supply member that is a member for supplying power to the internal electrode and is inserted through the through hole, and an insulating member arranged between the inner surface of the through hole and the power supply member. The insulating member includes a tubular first insulating member and a tubular second insulating member that covers a part of the first insulating member on an outer peripheral side, and the first insulating member and the second insulating member cover the inner surface of the through hole from an end part on one side to an end part on another side of the through hole. The electrostatic chuck further includes a discharge prevention member for preventing an electric discharge along a path from the power supply member to the inner surface of the through hole passing between the first insulating member and the second insulating member.

In the electrostatic chuck having the above-described configuration, while the first insulating member and the second insulating member are included as insulating members, an electric discharge along the path passing between both members can be securely prevented by the discharge prevention member.

According to the present invention, it is possible to provide an electrostatic chuck in which an electric discharge between a power supply member and a base plate can be prevented.

### BRIEF DESCRIPTION OF THE DRAWINGS

FIG. 1 is a cross sectional view schematically illustrating a configuration of an electrostatic chuck according to a first embodiment;

FIG. 2 is an expanded view of a configuration of a part of the electrostatic chuck according to the first embodiment;

FIG. 3 is a diagram for explaining a discharge path in an electrostatic chuck according to a comparative example;

FIG. 4 is an expanded view of a configuration of a part of an electrostatic chuck according to a second embodiment;

FIG. 5 is an expanded view of a configuration of a part of an electrostatic chuck according to a third embodiment;

FIG. 6 is an expanded view of a configuration of a part of an electrostatic chuck according to a fourth embodiment; and

FIG. 7 is an expanded view of a configuration of a part of an electrostatic chuck according to a fifth embodiment.

### DETAILED DESCRIPTION

Hereinafter, the present embodiment will be described with reference to the accompanying drawings. To ease understanding of the descriptions, in each drawing, the same components are denoted by the same reference signs as much as possible, and duplicate descriptions are not repeated.

A first embodiment will be described. An electrostatic chuck 10 according to the present embodiment is configured to adsorb and hold a wafer W set as a process target by an electrostatic force inside a semiconductor manufacturing apparatus such as, for example, an etching apparatus which is not illustrated in the drawing. The wafer W is, for example, a silicon wafer. The electrostatic chuck 10 may be used in an apparatus other than the semiconductor manufacturing apparatus.

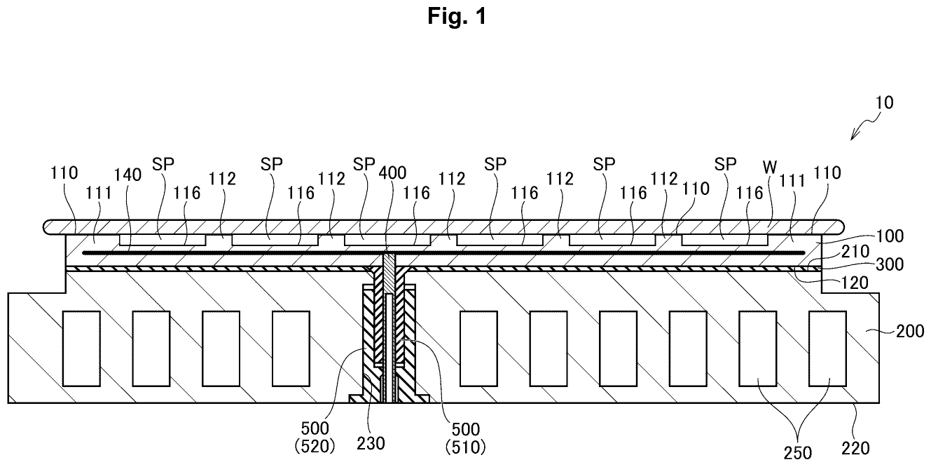

FIG. 1 is a cross sectional view schematically illustrating a configuration of the electrostatic chuck 10 in a state in which the wafer W is adsorbed and held. The electrostatic chuck 10 includes a dielectric substrate 100 and a base plate 200.

The dielectric substrate 100 is a substantially disk-shaped member formed of a ceramic sintered body. The dielectric substrate 100 contains, for example, highly pure aluminum oxide (Al₂O₃), but may contain other materials. A ceramics purity or type, an additive, or the like in the dielectric substrate 100 may be appropriately set by taking into account plasma resistance or the like needed for the dielectric substrate 100 in the semiconductor manufacturing apparatus.

A surface 110 on an upper side in FIG. 1 in the dielectric substrate 100 serves as a “placement surface” on which the wafer W is placed. A surface 120 on a lower side in FIG. 1 in the dielectric substrate 100 serves as a “surface to be joined” which is joined to the base plate 200 via a joining layer 300 which will be described later. A perspective in a case where the electrostatic chuck 10 is viewed from the surface 110 side along a direction perpendicular to the surface 110 will also be hereinafter expressed as “top view”.

An internal electrode 140 is provided inside the dielectric substrate 100. The internal electrode 140 is a thin planar layer made of a metallic material such as, for example, tungsten, and is arranged so as to be parallel to the surface 110. As a material of the internal electrode 140, molybdenum, platinum, palladium, and the like may be used in addition to tungsten. The internal electrode 140 is also referred to as an “RF electrode”, and used as one of a pair of counter electrodes for generating plasma in the semiconductor manufacturing apparatus. When power is supplied to the internal electrode 140 via a power supply member 400 which will be described later, plasma is generated, and the plasma is attracted to the wafer W side. The power supply member 400 and surrounding configurations will be described later.

An adsorption electrode is provided inside the dielectric substrate 100 in addition to the internal electrode 140, but is not illustrated in FIG. 1. The adsorption electrode is provided at a position closer to the surface 110 side than the internal electrode 140. When a voltage is applied to the adsorption electrode which is not illustrated in the drawing from an outside via a feed line which is not illustrated in the drawing, an electrostatic force is generated between the surface 110 and the wafer W, and according to this, the wafer W is adsorbed and held. The adsorption electrode may be provided as an electrode separate from the internal electrode 140 as described above, or the internal electrode 140 may be configured to be also used as the adsorption electrode.

As illustrated in FIG. 1, a space SP is formed between the dielectric substrate 100 and the wafer W. When a process such as etching is performed in the semiconductor manufacturing apparatus, an inert gas for temperature regulation is supplied to the space SP from the outside via a gas hole which is not illustrated in the drawing. When the inert gas is caused to be present between the dielectric substrate 100 and the wafer W, a thermal resistance between the dielectric substrate 100 and the wafer W is regulated, and according to this, a temperature of the wafer W is maintained at an appropriate temperature. As the inert gas for temperature regulation to be supplied to the space SP, a helium gas is used in the present embodiment, but the inert gas may be a gas of a type different from the helium gas.

A seal ring 111 and a dot 112 are provided on the surface 110 which serves as the placement surface, and the space SP described above is formed around the seal ring 111 and the dot 112.

The seal ring 111 is a wall which defines the space SP in a position corresponding to an outermost circumference. An upper end of the seal ring 111 becomes a part of the surface 110 and abuts against the wafer W. It is noted that the seal ring 111 may include a plurality of seal rings 111 provided so as to divide the space SP. With such a configuration, a pressure of the helium gas in each of the spaces SP can be individually regulated, and a surface temperature distribution of the wafer W during the process can be set to be close to uniformity.

A part denoted by reference sign “116” in FIG. 1 is a bottom of the space SP. Hereinafter, this part may also be referred to as a “bottom 116”. The seal ring 111 is formed as a result of digging a part of the surface 110 to a position of the bottom 116 together with the dot 112 which will be described next. The bottom 116 is parallel to the surface 110.

The dot 112 is a circular protrusion which protrudes from the bottom 116. The dot 112 includes a plurality of dots 112 to be provided. The plurality of dots 112 are substantially uniformly distributed and arranged on the placement surface of the dielectric substrate 100. An upper end of each of the dots 112 becomes a part of the surface 110 and abuts against the wafer W. By providing the plurality of thus configured dots 112, warping of the wafer W is reduced.

The base plate 200 is a substantially disk-shaped member which supports the dielectric substrate 100. The base plate 200 is made of, for example, a metallic material such as aluminum. The base plate 200 is joined to the surface 120 of the dielectric substrate 100 via the joining layer 300. A surface 210 on the upper side in FIG. 1 in the base plate 200 serves as a “surface to be joined” which is joined to the dielectric substrate 100.

The joining layer 300 is a layer provided between the dielectric substrate 100 and the base plate 200 to join those components. The joining layer 300 is obtained by causing an adhesive made of an insulating material to be cured. According to the present embodiment, a silicone adhesive is used as the above-described adhesive. It is noted however that the joining layer 300 may be obtained by causing an adhesive made of other types to be cured. In any case, in order that a thermal resistance between the dielectric substrate 100 and the base plate 200 is reduced, a material with a highest possible thermal conductivity is preferably used as the material of the joining layer 300.

An insulating film may be formed on a surface of the base plate 200. As the insulating film, for example, an alumina film formed by thermal spraying can be used. When the surface of the base plate 200 is covered by the insulating film, it is possible to increase a withstand voltage of the base plate 200.

A coolant flow path 250 through which a coolant flows is formed inside the base plate 200. When the process such as etching is performed in the semiconductor manufacturing apparatus, the coolant is supplied from the outside to the coolant flow path 250, and according to this, the base plate 200 is cooled down. Heat generated in the wafer W during the process is transferred to the coolant via the helium gas in the space SP, the dielectric substrate 100, and the base plate 200, and the heat is exhausted to the outside together with the coolant. The supply and exhaustion of the coolant to and from the coolant flow path 250 are performed via openings which are not illustrated in the drawing and which are formed in a surface 220 opposite to the surface 210 in the base plate 200.

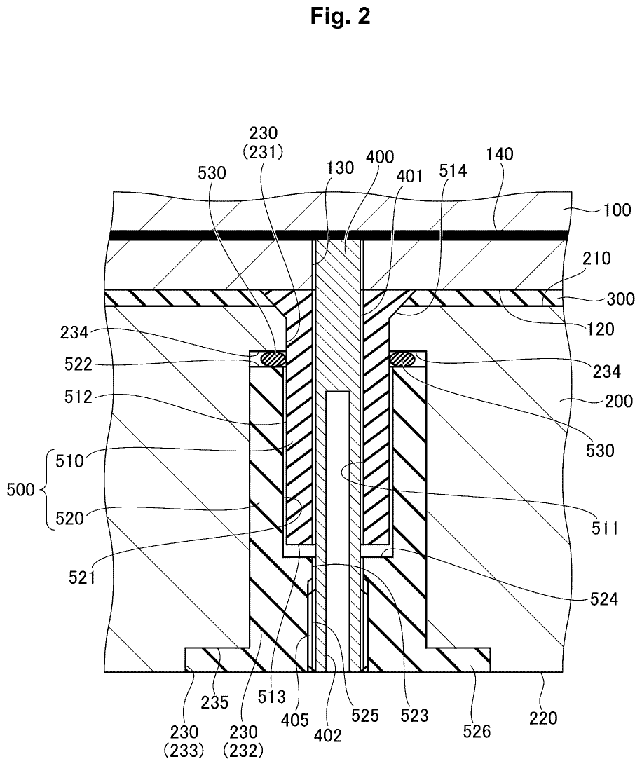

The power supply member 400 and surrounding configurations will be described mainly with reference to FIG. 2. As described above, the power supply member 400 is a member for supplying power to the internal electrode 140. The power supply member 400 is a stick-shaped member, and constituted of a material having electrical conductivity such as metal, for example. An end part on the upper side in FIG. 1 or FIG. 2 of the power supply member 400 abuts against the internal electrode 140. The power supply member 400 projects toward the base plate 200 side with respect to the surface 120 of the dielectric substrate 100. A through hole 230 is formed in the base plate 200, and the power supply member 400 is inserted through the inner part of the through hole 230.

As illustrated in FIG. 2, a circular recessed part 130 that is retreated toward the internal electrode 140 side is formed on the surface 120 of the dielectric substrate 100. The recessed part 130 is a bottomed hole, and the internal electrode 140 is exposed at a bottom of the recessed part 130. The power supply member 400 is inserted through the inner part of the recessed part 130, and one end of the power supply member 400 is pressed against the internal electrode 140 that is exposed as described above.

In the power supply member 400, a recessed part 402 is formed at an end part opposite to the end part pressed against the internal electrode 140. The recessed part 402 is a portion that receives a power supply pin which is not illustrated in the drawing for supplying power from the outside. When a process is performed in the semiconductor manufacturing apparatus, the power supply pin is inserted into the recessed part 402.

On an outer surface 401 of the power supply member 400, a male screw 405 is formed at a portion in a vicinity of the end part at which the recessed part 402 is formed. The male screw 405 is screwed with a female screw 525 formed on an insulating member 500 which will be described later. Due to this, by rotating the power supply member 400 about a center axis thereof, the power supply member 400 can be moved along the center axis, and one end thereof can be pressed against the internal electrode 140.

At this point, to prevent one end of the power supply member 400 from being strongly pressed against the internal electrode 140, an expansion mechanism which is not illustrated in the drawing may be provided in the power supply member 400. That is, it is possible to provide an expansion mechanism with which, when one end of the power supply member 400 is pressed against the internal electrode 140, a total length of the power supply member 400 is shortened due to a reaction force received from the internal electrode 140. At this point, if the power supply member 400 is configured so as to return to an original length due to elasticity, a force applied to the internal electrode 140 from the power supply member 400 can be suppressed to be appropriate. In place of providing such an expansion mechanism, a member having elasticity and electrical conductivity may be interposed between a distal end of the power supply member 400 and the internal electrode 140.

Alternatively, an electrode terminal electrically connected to the internal electrode 140 may be provided on the surface 120 of the dielectric substrate 100, and the distal end of the power supply member 400 may be caused to abut against the electrode terminal. That is, an aspect in which the power supply member 400 does not directly abut against the internal electrode 140 may be adopted.

As described above, the through hole 230 is formed in the base plate 200, and the power supply member 400 is inserted through this through hole 230. The through hole 230 is formed so as to perpendicularly pass through the surface 210 and the surface 220 of the base plate 200. From the surface 210 to the surface 220, a cross-sectional shape of the through hole 230 at each height position is a circular shape. However, an inner diameter of the through hole 230 is not entirely fixed, and varies depending on the height position.

An inner surface of the through hole 230 includes a first inner surface 231, a second inner surface 232, and a third inner surface 233. The first inner surface 231 is a portion closest to the surface 210 side of the inner surface of the through hole 230. The third inner surface 233 is a portion closest to the surface 220 side of the inner surface of the through hole 230. The second inner surface 232 is a portion between the first inner surface 231 and the third inner surface 233 of the inner surface of the through hole 230. The inner diameter of the through hole 230 is substantially fixed at each portion. The inner diameter of the second inner surface 232 is larger than the inner diameter of the first inner surface 231, and the inner diameter of the third inner surface 233 is further larger than the inner diameter of the second inner surface 232.

The inner surface of the through hole 230 that is present between the first inner surface 231 and the second inner surface 232 and is parallel to the surface 210 is also referred to as a “surface 234” hereinafter. The inner surface of the through hole 230 that is present between the second inner surface 232 and the third inner surface 233 and is parallel to the surface 210 is also referred to as a “surface 235” hereinafter.

The inner surface of the through hole 230 and the internal electrode 140 both have electrical conductivity, and are opposed to each other. Due to this, when a voltage is applied to the power supply member 400, there is a concern that an electric discharge may be caused between them. Thus, the tubular insulating member 500 is arranged between the inner surface of the through hole 230 and the internal electrode 140, and according to this, an electric discharge as described above is prevented. As a material of the insulating member 500, a material having an insulation property such as alumina or resin is used, for example.

The insulating member 500 is not a single member as a whole, and includes a first insulating member 510 and a second insulating member 520 as members separate from each other. The first insulating member 510 and the second insulating member 520 both have a substantially cylindrical shape. A center axis of the first insulating member 510 and a center axis of the second insulating member 520 both match a center axis of the internal electrode 140.

An end part on the dielectric substrate 100 side of the first insulating member 510 abuts against the surface 120 of the dielectric substrate 100. An end part 513 opposite to the above-described end part of the first insulating member 510 is present inside the base plate 200, that is, at a position between the surface 210 and the surface 220. Accordingly, the first insulating member 510 does not cover the whole inner surface of the through hole 230 but covers only the portion on the surface 210 side of the inner surface.

The power supply member 400 extends to a position closer to the surface 220 side (lower side in FIG. 2) than the end part 513 of the first insulating member 510. An outer diameter of the first insulating member 510 is substantially the same as the inner diameter of the first inner surface 231 of the through hole 230. A slight gap is formed between the inner surface 511 of the first insulating member 510 and the outer surface 401 of the internal electrode 140.

In FIG. 2, a portion denoted by reference sign “514” is a portion in a vicinity of an end part on the upper side of an outer surface 512 of the first insulating member 510. This portion will also be hereinafter referred to as an “expanded-diameter part 514”. A shape of the expanded-diameter part 514 is a tapered shape in which an outer diameter is gradually increased as being closer to the surface 120 of the dielectric substrate 100. A shape of the first inner surface 231 at this portion is also a tapered shape corresponding to the expanded-diameter part 514.

The second insulating member 520 covers a part of the first insulating member 510 on the outer peripheral side. An end part on the lower side in FIG. 2 of the second insulating member 520 is at the same height position as that of the surface 220. An end part 522 on the upper side in FIG. 2 of the second insulating member 520 is present inside the base plate 200, that is, at a position between the surface 210 and the surface 220. Accordingly, the second insulating member 520 does not cover the whole inner surface of the through hole 230 but covers only the portion on the surface 220 side of the inner surface.

The end part 522 of the second insulating member 520 is at a position closer to the surface 210 side than the end part 513 of the first insulating member 510 along a center axis of the through hole 230. In other words, the end part 513 of the first insulating member 510 is at a position closer to the surface 220 side than the end part 522 of the second insulating member 520 along the center axis of the through hole 230.

In this way, in the present embodiment, the first insulating member 510 covering the portion on the surface 210 side of the inner surface of the through hole 230 is overlapped with the second insulating member 520 covering the portion on the surface 220 side of the inner surface, and the whole inner surface of the through hole 230 is covered by these two members. With such a configuration, even if variation is caused in dimensions of each member such as the first insulating member 510 (particularly, a dimension in an upper and lower direction in FIG. 2), there is no possibility that a part of the inner surface of the through hole 230 is not covered by the insulating member 500.

The first insulating member 510 and the second insulating member 520 cover the inner surface of the through hole 230 as described above. Herein, “cover” means to prevent the inner surface of the through hole 230 from being directly opposed to the power supply member 400. A gap may be formed between the inner surface of the through hole 230 and the first insulating member 510 or the second insulating member 520 covering the inner surface.

The end part 522 of the second insulating member 520 is opposed to the surface 234 of the base plate 200, and a gap is formed between the end part 522 and the surface 234. An annular member 530 is arranged in the gap. The annular member 530 is an electrical insulating member having elasticity such as rubber, for example, and has an annular shape. The annular member 530 is sandwiched and compressed by the end part 522 and the surface 234.

In FIG. 2, a portion denoted by reference sign “521” is a portion of the inner surface of the second insulating member 520 opposed to the outer surface 512 of the first insulating member 510. This portion will also be hereinafter referred to as an “inner surface 521”. A slight gap is formed between the inner surface 521 and the outer surface 512.

In FIG. 2, a portion denoted by reference sign “523” is a portion of the inner surface of the second insulating member 520 directly opposed to the outer surface 401 of the power supply member 400 without the first insulating member 510 therebetween. This portion will also be hereinafter referred to as an “inner surface 523”. An inner diameter of the inner surface 523 is smaller than an inner diameter of the inner surface 521. A slight gap is formed between the inner surface 523 and the outer surface 401. The female screw 525 is formed on a part of the inner surface 523. As described above, the female screw 525 is screwed with the male screw 405 formed on the outer surface 401 of the power supply member 400.

The inner surface of the second insulating member 520 that is present between the inner surface 521 and the inner surface 523 and is parallel to the surface 210 is also referred to as a “surface 524” hereinafter. The surface 524 is opposed to the end part 513 of the first insulating member 510. A gap is formed between the surface 524 and the end part 513.

At an end part closest to the surface 220 side of the second insulating member 520, a flange 526 that is an expanded-diameter portion is provided. An outer diameter of the flange 526 substantially equal to an inner diameter of the third inner surface 233. The flange 526 abuts against the surface 235 from the lower side, and according to this, a position of the second insulating member 520 in the upper and lower direction in FIG. 2 is defined. The second insulating member 520 is fixed to the base plate 200, for example, by press fitting, bonding, and the like.

As described above, in the present embodiment, the first insulating member 510 and the second insulating member 520 cover the whole inner surface of the through hole 230 from the end part on one side to the end part on the other side of the through hole 230.

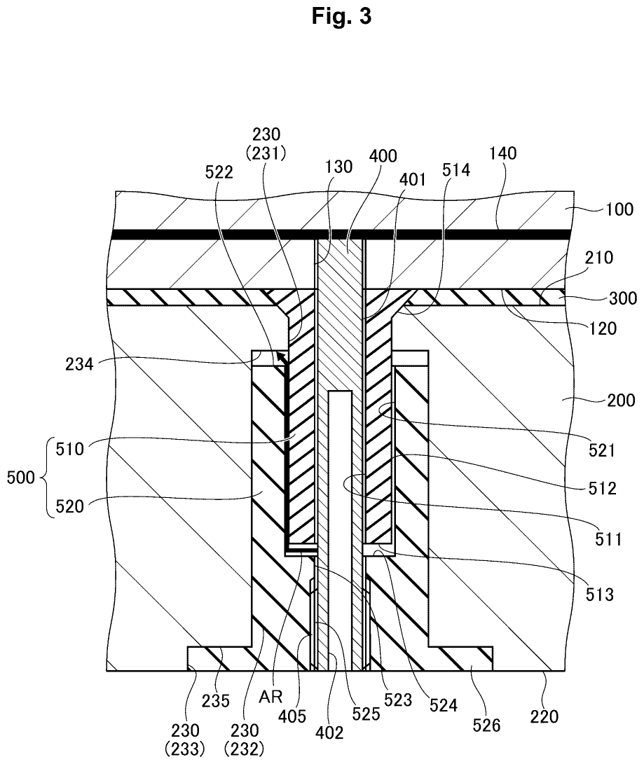

However, with such a configuration, an electric discharge may be caused between the power supply member and the base plate on a path passing through a gap between the first insulating member 510 and the second insulating member 520. Specifically, an electric discharge from the power supply member 400 to the inner surface of the through hole 230 may be caused along a path indicated by an arrow AR in FIG. 3, for example.

Thus, in the present embodiment, the annular member 530 is sandwiched between the distal end (end part 522) of the second insulating member 520 and the surface 234 of the base plate 200 to prevent the above-described electric discharge from being caused. The annular member 530 is an elastic member, and is sandwiched and compressed between the end part 522 and the surface 234. Due to this, the annular member 530 blocks the gap between the first insulating member 510 and the second insulating member 520 (specifically, the gap between the inner surface 521 and the outer surface 512), and interrupts a path through which an electric discharge may be caused. To securely prevent an electric discharge, the annular member 530 preferably abuts against the outer surface 512 of the first insulating member 510 over the entire circumference. An aspect in which a part of the compressed and deformed annular member 530 enters the gap between the inner surface 521 and the outer surface 512 may be adopted.

The annular member 530 is a member for preventing an electric discharge along a path from the power supply member 400 to the inner surface of the through hole 230 passing between the first insulating member 510 and the second insulating member 520, and corresponds to the “discharge prevention member” in the present embodiment.

As a material of the annular member 530, an optional material can be used so long as it is an electrical insulating material having elasticity. For example, a material such as silicone rubber or fluorine-based polymer can be used.

The configurations of the power supply member 400, the insulating member 500, and the like described above may be applied not only to a feed line connected to the internal electrode 140 (that is, the RF electrode) but also to a feed line connected to an adsorption electrode which is not illustrated in the drawing.

In the present embodiment, the first insulating member 510 covers the portion on the surface 210 side of the inner surface of the through hole 230, and the second insulating member 520 covers the portion on the surface 220 side of the inner surface of the through hole 230. Such a positional relation between the first insulating member 510 and the second insulating member 520 may be reversed from the above-described relation. That is, the second insulating member 520 may cover the portion on the surface 210 side of the inner surface of the through hole 230, and the first insulating member 510 may cover the portion on the surface 220 side of the inner surface of the through hole 230.

A second embodiment will be described. Hereinafter, an aspect different from the first embodiment will be mainly described, and descriptions on an aspect common to the first embodiment are not repeated as appropriate.

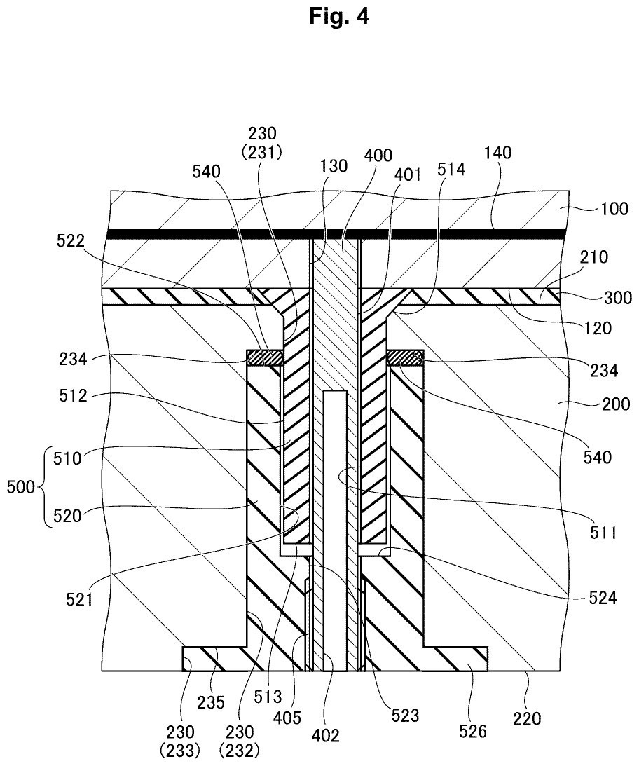

FIG. 4 illustrates configurations of the power supply member 400 according to the present embodiment and portions in the vicinity thereof from the same viewpoint as in FIG. 2. In the present embodiment, an annular member 540 is provided in place of the annular member 530. The annular member 540 is an electrical insulating material having elasticity. The annular member 540 is a member that is fixed in advance to the distal end (end part 522) of the second insulating member 520 before the second insulating member 520 is attached to the base plate 200. The annular member 540 is attached to the end part 522 over the entire surface, so that the annular member 540 has an annular shape. As a material of the annular member 540, for example, a material such as silicone rubber or fluorine-based polymer can be used. The annular member 540 may be fixed to the end part 522 by bonding and the like, or may be formed by applying rubber coating to the end part 522, for example.

When the second insulating member 520 is inserted through the inner part of the through hole 230, the annular member 540 is sandwiched and compressed between the end part 522 and the surface 234 of the base plate 200. At this point, the deformed annular member 540 abuts against the outer surface 512 of the first insulating member 510 over the entire circumference. As a result, similarly to the annular member 530 in the first embodiment, the annular member 540 blocks the gap between the inner surface 521 and the outer surface 512, and interrupts a path on which an electric discharge may be caused. The annular member 540 corresponds to the “discharge prevention member” in the present embodiment. In such an aspect too, an effect similar to that described in the first embodiment can be exhibited.

In the present embodiment, there is also an advantage such that reassembly after disassembly is facilitated by fixing in advance the annular member 540 to the end part 522 of the second insulating member 520.

A third embodiment will be described. Hereinafter, an aspect different from the first embodiment will be mainly described, and descriptions on an aspect common to the first embodiment are not repeated as appropriate.

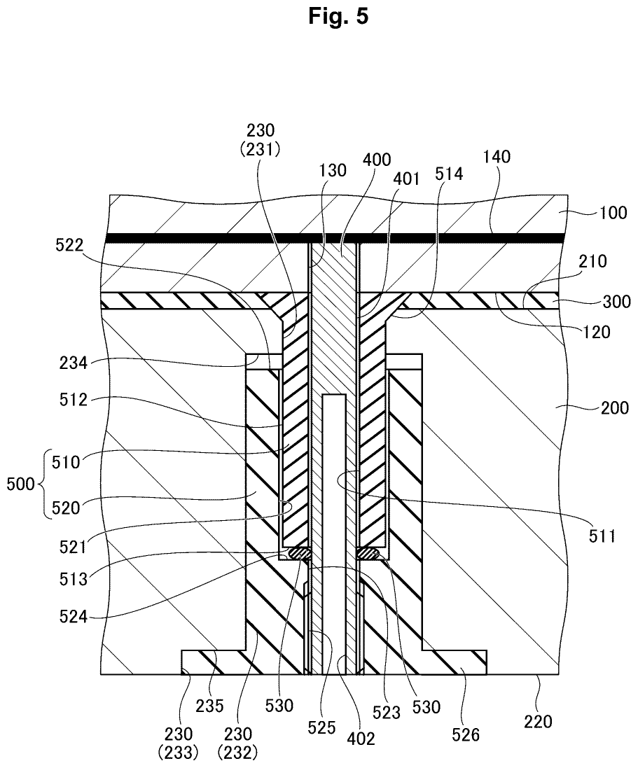

FIG. 5 illustrates configurations of the power supply member 400 according to the present embodiment and portions in the vicinity thereof from the same viewpoint as in FIG. 2. In the present embodiment, the annular member 530 is arranged in a gap between the end part 513 of the first insulating member 510 and the surface 524 of the second insulating member 520, and is sandwiched and compressed therebetween. Similarly to the first embodiment, the annular member 530 blocks the gap between the first insulating member 510 and the second insulating member 520 (specifically, the gap between the inner surface 521 and the outer surface 512), and interrupts a path on which an electric discharge may be caused. To securely prevent an electric discharge, the annular member 530 preferably abuts against the outer surface 512 of the first insulating member 510 over the entire circumference. An aspect in which a part of the compressed and deformed annular member 530 enters the gap between the inner surface 521 and the outer surface 512 may be adopted. In such an aspect too, an effect similar to that described in the first embodiment can be exhibited.

A fourth embodiment will be described. Hereinafter, an aspect different from the first embodiment will be mainly described, and descriptions on an aspect common to the first embodiment are not repeated as appropriate.

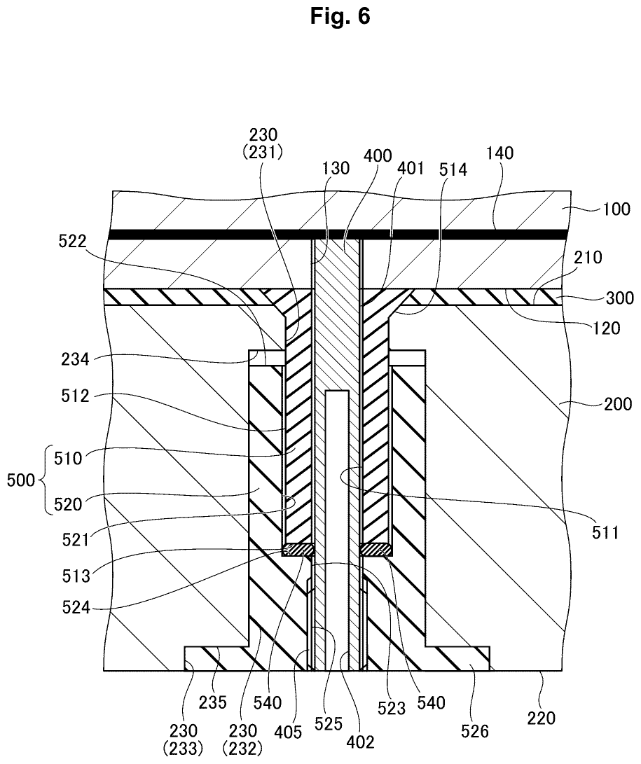

FIG. 6 illustrates configurations of the power supply member 400 according to the present embodiment and portions in the vicinity thereof from the same viewpoint as in FIG. 2. In the present embodiment, the annular member 540 described in the second embodiment (FIG. 4) is fixed in advance to the end part 513 of the first insulating member 510 instead of the end part 522 of the second insulating member 520.

The annular member 540 in the present embodiment is a member that is fixed in advance to the distal end (end part 513) of the first insulating member 510 before the first insulating member 510 is arranged inside the through hole 230. The annular member 540 is attached to the end part 513 over the entire surface, so that the annular member 540 has an annular shape. As a material of the annular member 540, for example, a material such as silicone rubber or fluorine-based polymer can be used. The annular member 540 may be fixed to the end part 513 by bonding and the like, or may be formed by applying rubber coating to the end part 513, for example.

When the first insulating member 510 and the second insulating member 520 are inserted through the inner part of the through hole 230, the annular member 540 is sandwiched and compressed between the end part 513 of the first insulating member 510 and the surface 524 of the second insulating member 520. At this point, the deformed annular member 540 abuts against the outer surface 512 of the first insulating member 510 over the entire circumference. As a result, similarly to the annular member 530 in the first embodiment, the annular member 540 blocks the gap between the inner surface 521 and the outer surface 512, and interrupts a path on which an electric discharge may be caused. The annular member 540 corresponds to the “discharge prevention member” in the present embodiment. In such an aspect too, an effect similar to that described in the first embodiment can be exhibited.

In the present embodiment, there is also an advantage such that reassembly after disassembly is facilitated by fixing in advance the annular member 540 to the end part 513 of the first insulating member 510.

A fifth embodiment will be described. Hereinafter, an aspect different from the first embodiment will be mainly described, and descriptions on an aspect common to the first embodiment are not repeated as appropriate.

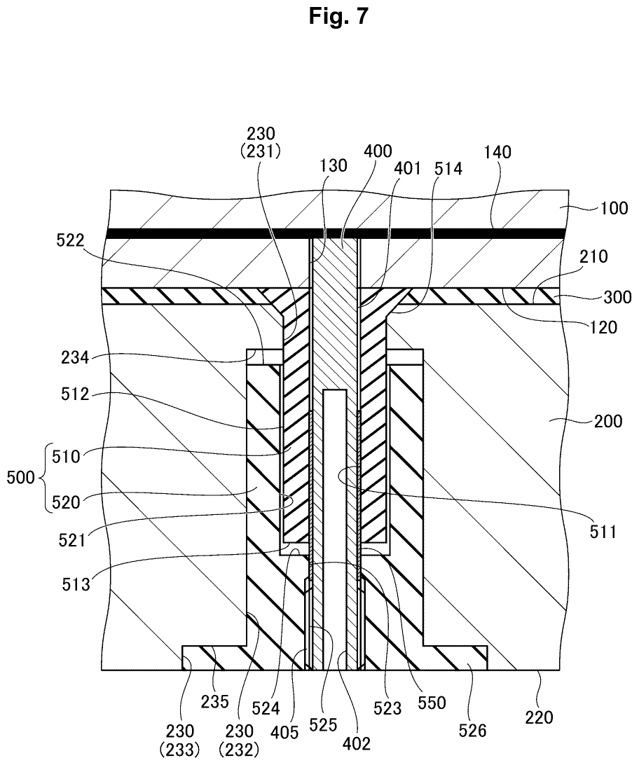

FIG. 7 illustrates configurations of the power supply member 400 according to the present embodiment and portions in the vicinity thereof from the same viewpoint as in FIG. 2. In the present embodiment, an insulating cover 550 is provided in place of the annular member 530. The insulating cover 550 is a sheet-like member that is provided so as to cover a part of the outer surface 401 of the power supply member 400 over the entire circumference on the outer side. A material of the insulating cover 550 has an electrical insulation property. The insulating cover 550 is preferably provided so as to cover at least a portion of the outer surface 401 opposed to a part between the end part 513 and the inner surface 523. That is, the insulating cover 550 is preferably provided so as to cover at least a portion that may become a starting point of an electric discharge as illustrated in FIG. 3.

The insulating cover 550 may be a rubber coat that covers the outer surface 401, or may be a thermal contraction tube. The insulating cover 550 may also be a coating made of a material such as vinyl chloride, silicone rubber, or fluoride polymer. When the insulating cover 550 is provided, the occurrence of an electric discharge passing between the first insulating member 510 and the second insulating member 520 is prevented. The insulating cover 550 corresponds to the “discharge prevention member” in the present embodiment. In such an aspect too, an effect similar to that described in the first embodiment can be exhibited.

The present embodiment has been described above with reference to the specific examples. However, the present disclosure is not limited to these specific examples. Configurations obtained by adding appropriate design modifications to these specific examples by a person skilled in the art are also within the scope of the present disclosure as long as the configurations have a feature of the present disclosure. Each of the elements included in each of the specific examples described above and arrangements, conditions, shapes, and the like of the elements are not limited to those illustrated and can be modified as appropriate. For each of the elements included in each of the specific examples described above, a combination can be appropriately changed as long as a technical contradiction does not occur.

What is claimed is:

1. An electrostatic chuck comprising:
a dielectric substrate including a placement surface on which an object to be adsorbed is placed;
an internal electrode provided inside the dielectric substrate;
a base plate that is a metal member configured to support the dielectric substrate, and in which a through hole is formed;
a power supply member that is a member for supplying power to the internal electrode and inserted through the through hole; and
an insulating member arranged between an inner surface of the through hole and the power supply member, wherein
the insulating member includes:
a tubular first insulating member; and
a tubular second insulating member covering a part of the first insulating member on an outer peripheral side,
the first insulating member and the second insulating member cover the inner surface of the through hole from an end part on one side to an end part on another side of the through hole, and
the electrostatic chuck further comprises a discharge prevention member for preventing an electric discharge along a path from the power supply member to the inner surface of the through hole passing between the first insulating member and the second insulating member.

2. The electrostatic chuck according to claim 1,
wherein the discharge prevention member is an electrical insulating member covering an outer surface of the power supply member.

3. The electrostatic chuck according to claim 1,
wherein the discharge prevention member is an electrical insulating member that is provided so as to block a gap between the first insulating member and the second insulating member.

4. The electrostatic chuck according to claim 3,
wherein the discharge prevention member is an elastic member.

5. The electrostatic chuck according to claim 4,
wherein the discharge prevention member is sandwiched and compressed between a distal end of the second insulating member and the base plate.

6. The electrostatic chuck according to claim 5,
wherein the discharge prevention member is fixed in advance to the distal end of the second insulating member.

7. The electrostatic chuck according to claim 4,
wherein the discharge prevention member is sandwiched and compressed between a distal end of the first insulating member and the second insulating member.

8. The electrostatic chuck according to claim 7,
wherein the discharge prevention member is fixed in advance to the distal end of the first insulating member.
